(19) United States
(12) Patent Application Publication
(10) Pub. No.: US 2022/0367624 A1
(43) Pub. Date: Nov. 17, 2022

(54) WORK FUNCTION MATERIAL AND MANUFACTURING PROCESS THEREOF

(71) Applicant: Taiwan Semiconductor Manufacturing Company Limited, Hsinchu (TW)

(72) Inventors: Hsin-Yi LEE, Hsinchu City (TW); Huang-Lin CHAO, Hillsboro, OR (US); Chi On CHUI, Hsinchu City (TW)

(21) Appl. No.: 17/565,220

(22) Filed: Dec. 29, 2021

Related U.S. Application Data
(60) Provisional application No. 63/188,893, filed on May 14, 2021.

(51) Int. Cl. H01L 29/06; H01L 29/423; H01L 29/786; H01L 29/66; H01L 21/8234

(52) U.S. Cl. CPC H01L 29/0665; H01L 29/42392; H01L 29/78618; H01L 29/78696; H01L 29/66742; H01L 21/823412; H01L 21/823418

(57) ABSTRACT

Some implementations described herein provide a method. The method includes forming a channel structure of a transistor. The method includes forming a work function metal (WFM), that includes aluminum and carbon, around the channel structure. Forming the WFM around the channel structure includes applying a chemical soak, with a material of the chemical soak including an aluminum, carbon, and hydrogen based material. The WFM includes a concentration of titanium that is in a range of 0% to less than 1.5% of the WFM. Some implementations described herein provide a transistor. The transistor includes a channel structure and an aluminum carbide (AlC)-based work function material (WFM) disposed around the channel structure. The WFM comprises a concentration of titanium that is in a range of 0% to less than 1.5% of the WFM.

### CROSS-REFERENCE TO RELATED APPLICATION

This patent application claims priority to U.S. Provisional Patent Application No. 63/188,893, filed on May 14, 2021, and entitled “ALUMINUM CARBIDE BASED WORK FUNCTION MATERIAL AND MANUFACTURING PROCESS THEREOF.” The disclosure of the prior application is considered part of and is incorporated by reference into this patent application.

### BACKGROUND

A field-effect transistor (FET) is a type of transistor that uses an electric field to control the flow of current. A FET includes three terminals: a source, a gate, and a drain. In operation, a FET controls the flow of current through the application of a voltage to the gate which, in turn, alters conductivity between the drain and the source. A commonly used type of FET is a metal-oxide-semiconductor field-effect transistor (MOSFET). A MOSFET can be used, for example, as a switch for an electrical signal (e.g., a radio frequency (RF) switch) or as an amplifier for an electrical signal (e.g., a low-noise amplifier (LNA)), among other examples. A gate-all-around (GAA) structure may be formed as a type of MOSFET in which channels extend through a gate material between epitaxial structures. GAA structures may have improved device density in a width dimension (e.g., a critical dimension) when compared to a fin field-effect transistor (FinFET) structure. For example, GAA structures may be formed with sub-7 nanometer dimensions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2E are diagrams of an example transistor described herein.

FIGS. 3A-3F are diagrams of an example implementation described herein.

FIGS. 4A-4B are diagrams of examples of work function material layers described herein.

FIG. 5 is a diagram of an example electronic device that includes multiple transistors described herein.

FIG. 6 is a diagram of an example transistor described herein.

FIG. 7 is a diagram of example components of one or more devices of FIG. 1 described herein.

FIG. 8 is a flowchart of an example process relating to forming a transistor described herein.

FIGS. 9A-9H are diagrams of an example implementation described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An electronic device may be formed having one or more transistors (e.g., field-effect transistors (FETs)) having threshold voltages (Vts). For example, the electronic device may include a first transistor configured with a relatively high Vt, and a second transistor configured with a relatively low Vt. The first transistor may be configured with an optimization for use in a first application and the second transistor may be configured with an optimization for use in a second application. Based on optimizing transistors for different applications, the electronic device may manage operations to use the first transistor (e.g., along with a set of similarly configured transistors) when a relatively high Vt improves device performance (e.g., current leakage reduction and/or operation speed, among other examples) and to use the second transistor (e.g., along with a set of similarly configured transistors) when a relatively low Vt improves device performance (e.g., power consumption, among other examples).

Manufacturing processes present challenges for configuring a Vt for a transistor based on materials used for a work function material (WFM) of the transistor. The transistor may be manufactured with a WFM that is formed of titanium, aluminum, and carbon (e.g., TiAlC) or that is formed of titanium nitride (e.g., TiN), among other examples. The titanium may be useful for bonding, during an atomic layer deposition operation, the WFM to a dielectric disposed on a channel structure of the transistor. However, the titanium may provide a constraint on a minimum thickness of the WFM. For example, the WFM may have a minimum thickness of 12 angstroms based on the WFM including titanium. The minimum thickness may provide a limitation to a Vt of the transistor. For example, the minimum thickness may correspond to a maximum Vt (e.g., a maximum contribution to the Vt that is attributed to the WFM).

Some implementations described herein provide techniques and apparatuses for configuring a Vt for a transistor. The transistor may be configured with a WFM, that includes aluminum and carbon, that is disposed around a channel structure. The WFM may be used instead of a titanium-based WFM or in addition to the titanium-based WFM to provide improved tuning of the WFM for Vt configuration. One or more semiconductor processing tools may form the WFM using a chemical soak deposition of material that forms the WFM. In some implementations, the one or more semiconductor processing tools may soak the transistor with triethylaluminium (Al₂(C₂H₅)₆) (TEA) to form the WFM.

The WFM may be titanium-free (e.g., having a concentration of titanium that is in a range of 0% to less than 1.5% of the WFM). In this way, the WFM may have a thickness that is in a range greater than 0 angstroms and less than 12 angstroms and/or may be tuned to a thickness in a range of greater than 12n angstroms and less than 12(n+1) angstroms, where n is based on a number of layers of a titanium-based WFM. Based on having improved tuning of the Vt of the transistor, the transistor may be optimized to improve power efficiency, operation speed, and/or current leakage, among other examples.

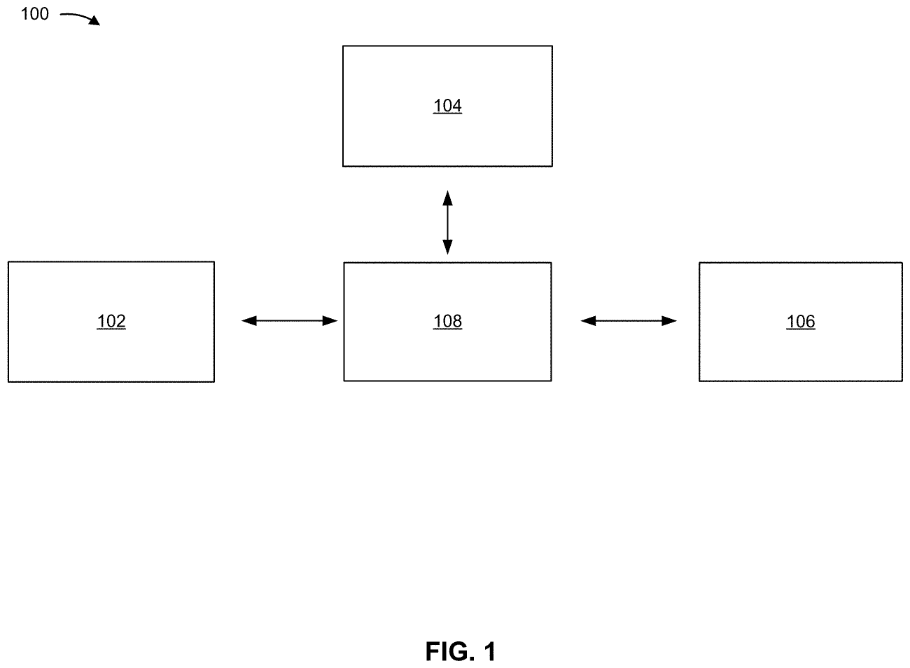

FIG. 1 is a diagram of an example environment 100 in which systems and/or methods described herein may be implemented. As shown in FIG. 1, environment 100 may include a plurality of semiconductor processing tools 102-106 and a wafer/die transport tool 108. The plurality of semiconductor processing tools 102-106 may include a deposition tool 102, an etching tool 104, a planarization tool 106, and/or another semiconductor processing tool. The tools included in the example environment 100 may be included in a semiconductor clean room, a semiconductor foundry, a semiconductor processing and/or manufacturing facility, or another location.

The deposition tool 102 is a semiconductor processing tool that is capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes a chemical soak tool in which a fluid (e.g., a liquid or a gas) is applied to the substrate for a configured amount of time. In some implementations, the example environment 100 includes a plurality of types of deposition tools 102.

The etching tool 104 is a semiconductor processing tool that is capable of etching various types of materials of a substrate, wafer, or semiconductor device. For example, the etching tool 104 may include a wet etching tool, a dry etching tool, and/or another type of etching tool. A wet etching tool may include a chemical etching tool or another type of wet etching tool that includes a chamber filled with an etchant. The substrate may be placed in the chamber for a particular time period to remove particular amounts of one or more portions of the substrate. A dry etching tool may include a plasma etching tool, a laser etching tool, a reactive ion etching tool, or a vapor phase etching tool, among other examples. A dry etching tool may remove one or more portions of a the substrate using a sputtering technique, a plasma-assisted etch technique (e.g., a plasma sputtering technique or another type of technique involving the use of an ionized gas to isotropically or directionally etch the one or more portions), or another type of dry etching technique.

The planarization tool 106 is a semiconductor processing tool that is capable of polishing or planarizing various layers of a wafer or semiconductor device. For example, the planarization tool 106 may include a chemical mechanical planarization (CMP) tool and/or another type of planarization tool that polishes or planarizes a layer or surface of deposited or plated material. The planarization tool 106 may polish or planarize a surface of a semiconductor device with a combination of chemical and mechanical forces (e.g., chemical etching and free abrasive polishing). The planarization tool 106 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

Wafer/die transport tool 108 includes a mobile robot, a robot arm, a tram or rail car, an overhead hoist transfer (OHT) vehicle, an automated material handling system (AMES), and/or another type of tool that is used to transport wafers and/or dies between semiconductor processing tools 102-106 and/or to and from other locations such as a wafer rack, a storage room, or another location. In some implementations, wafer/die transport tool 108 may be a programmed tool to travel a particular path and/or may operate semi-autonomously or autonomously.

The number and arrangement of tools shown in FIG. 1 are provided as one or more examples. In practice, there may be additional tools, fewer tools, different tools, or differently arranged tools than those shown in FIG. 1. Furthermore, two or more tools shown in FIG. 1 may be implemented within a single tool, or a single tool shown in FIG. 1 may be implemented as multiple, distributed tools. Additionally, or alternatively, a set of tools (e.g., one or more tools) of environment 100 may perform one or more functions described as being performed by another set of tools of environment 100.

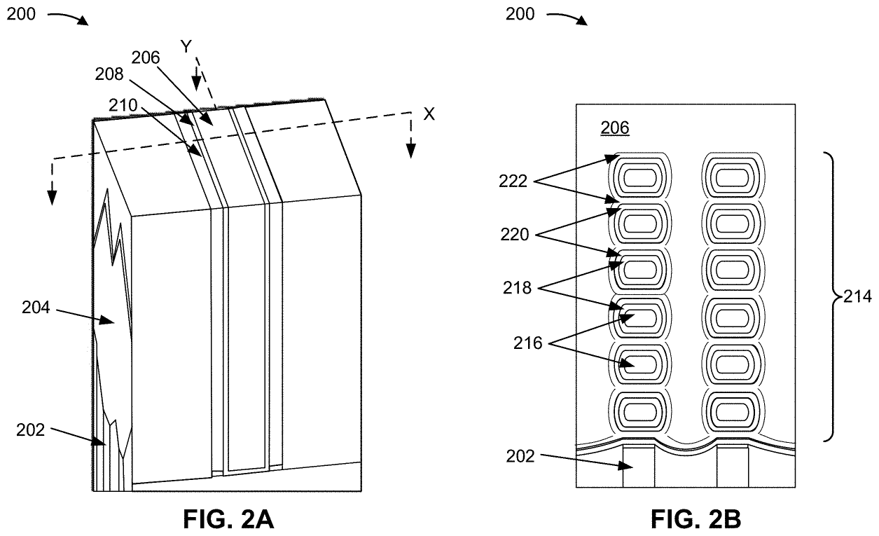

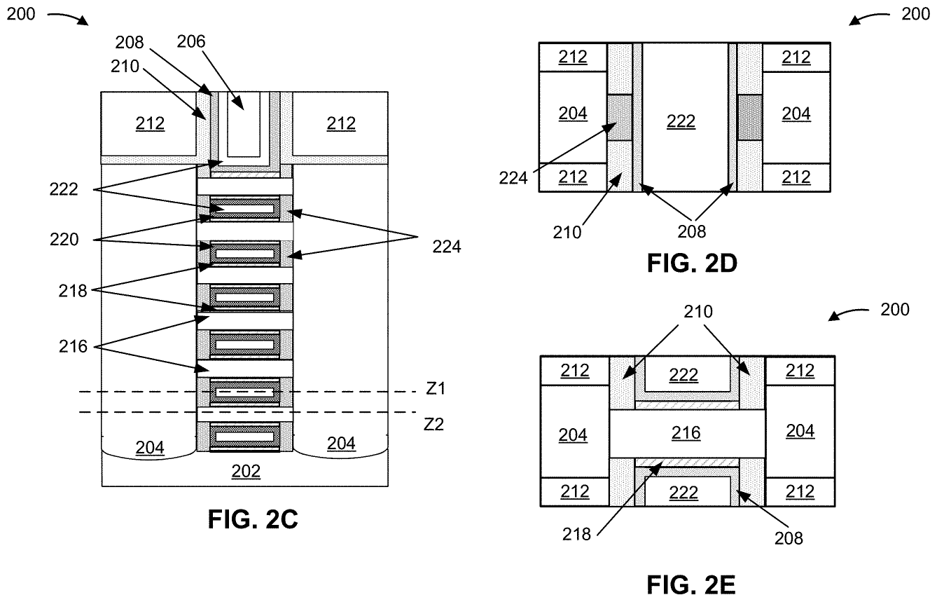

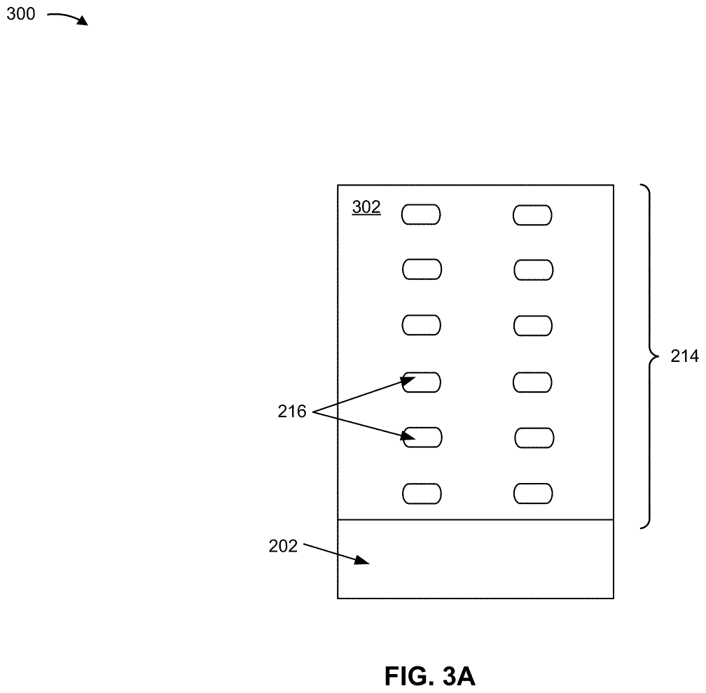

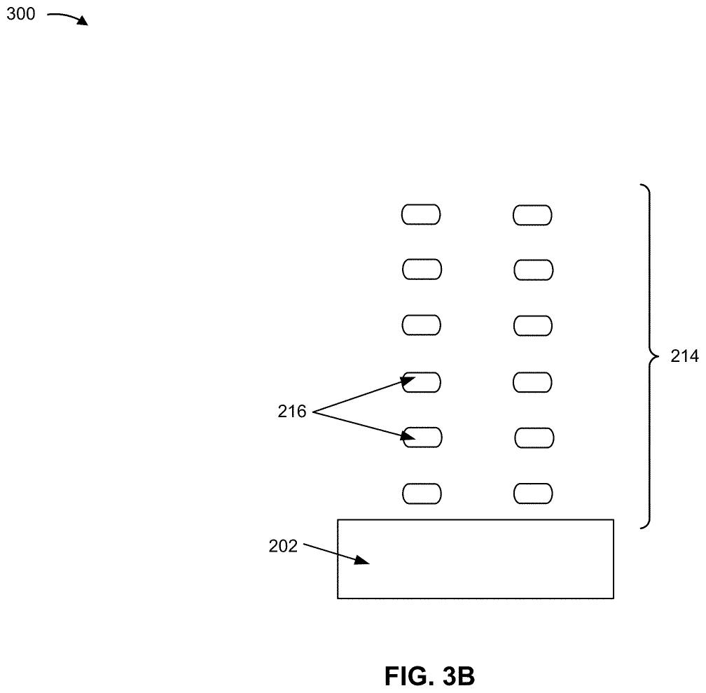

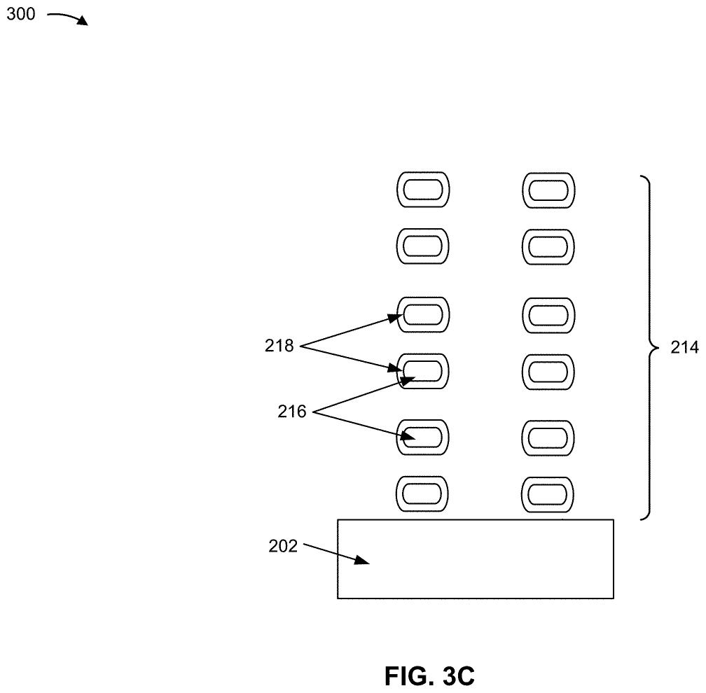

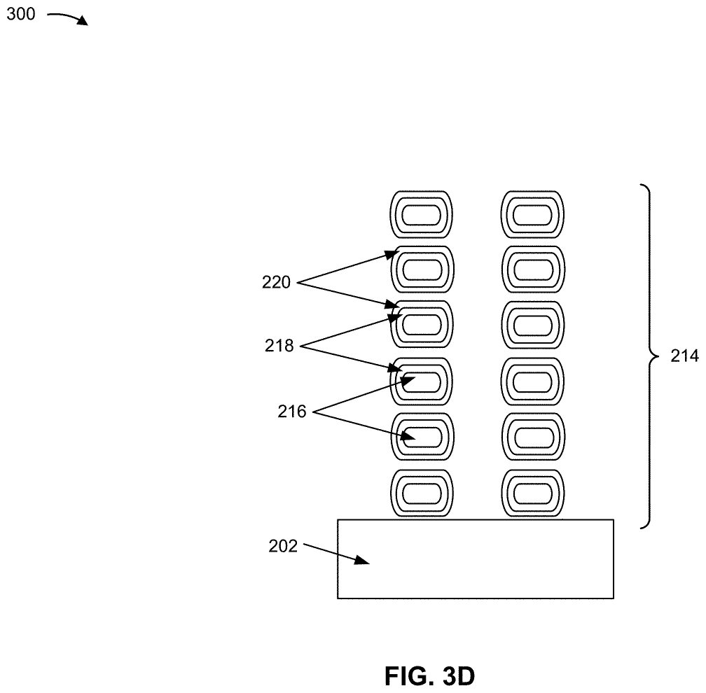

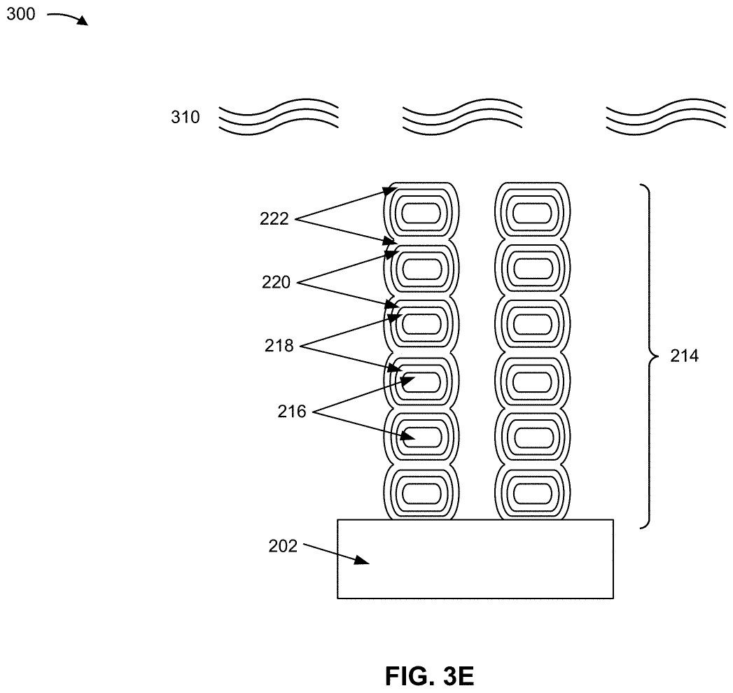

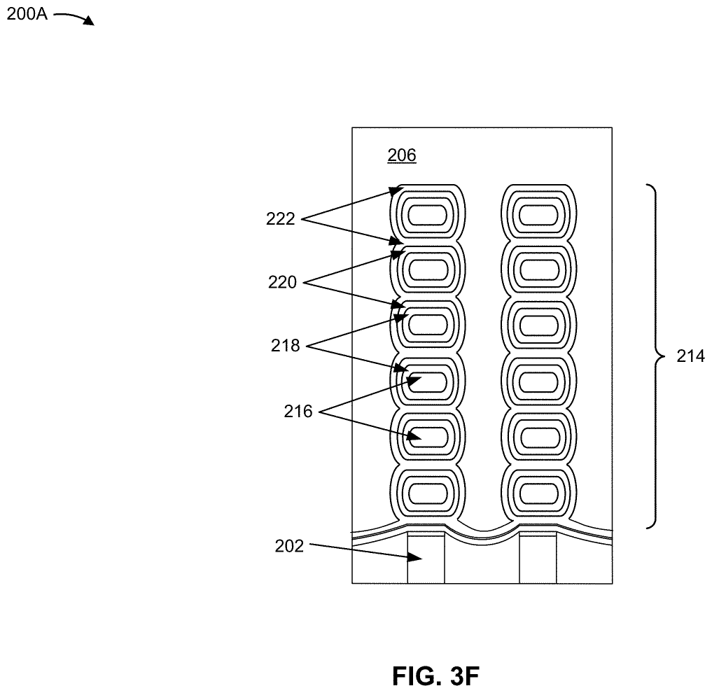

FIGS. 2A-2E are diagrams of an example transistor 200 described herein. The transistor 200 may include one or more additional layers and/or structures not shown in connection with FIGS. 2A-2E. The transistor 200 may be included in an electronic device that includes one or more additional semiconductor structures, such as one or more additional transistors. For example, the electronic device may include additional layers and/or dies formed on layers above and/or below the transistor 200 shown in FIGS. 2A-2E. The transistor 200 may be manufactured using an example process as described in connection with FIGS. 3A-3F. The transistor 200 may include, or may be included in, a nanosheet transistor. This disclosure applies to other types of transistors as well, such as FinFETs.

As shown in FIG. 2A, the transistor 200 includes a substrate 202. The substrate 202 may include a semiconductor die substrate, a semiconductor wafer, or another type of substrate in and/or on which semiconductor devices may be formed. In some implementations, the substrate 202 is formed of silicon (Si), a material including silicon, a III-V compound semiconductor material such as gallium arsenide (GaAs), a silicon on insulator (SOI), or another type of semiconductor material. The substrate 202 may include one or more fin structures disposed on a semiconductor material (e.g., a silicon-based material) and/or one or more dielectric structures (e.g., trench isolation structures) disposed around the one or more fin structures.

The transistor 200 may also include source/drains 204 extending upward from a top surface of the substrate 202. The source/drains 204 may include an epitaxial material, such as silicon, silicon germanium, and/or gallium nitride (GaN)-based materials, among other examples.

The transistor 200 may further include a filling metal 206 disposed between the source/drains 204 (e.g., between a source/drain 204 on a left side of the transistor 200 and a source/drain 204 on a right side of the transistor 200). The filling metal 206 may include a conductive material, such as titanium nitride and/or tungsten, among other examples. The filling metal 206 may provide electrical conduction between a WFM and a bit line or other conductive structure in electrical connection with the filling metal 206.

The filling metal 206 may be insulated from the source/drains 204 by a high-k dielectric layer 208, a gate spacer 210, and/or an inter-layer dielectric 212. The high-k dielectric layer 208 may include a hafnium-based material (e.g., hafnium silicate or hafnium dioxide, among other examples) or a zirconium-based material (zirconium silicate or zirconium dioxide, among other examples), among other examples. The high-k dielectric layer 208 may be disposed between the filling metal 206 and the gate spacer 210. The high-k dielectric layer 208 may have a thickness in a range from approximately 7 angstroms (A) to approximately 25 A. The gate spacer 210 may include a dielectric material, such as silicon dioxide, silicon nitride, or silicon oxynitride, among other examples. The gate spacer 210 may be disposed between the high-k dielectric layer 208 and the inter-layer dielectric 212. The gate spacer 210 may have a thickness in a range from approximately 15 A to approximately 300 A. The inter-layer dielectric 212 may surround the source/drains 204 on front, back, and/or top surfaces of the source/drains 204. The inter-layer dielectric 212 may include a low-k material, such as silicon dioxide, silicon nitride, or silicon oxynitride, among other examples. The inter-layer dielectric 212 may provide structural support to the transistor 200 and electrical insulation between structures within the transistor 200. The inter-layer dielectric 212 may have a thickness in a range from approximately 7 A to approximately 25 A

FIG. 2A shows an X cross-section line (e.g., a logical dividing line to show an interior of the transistor 200) that extends between a left side of the transistor 200 and a right side of the transistor 200. FIG. 2A also shows a Y cross-section line that extends between a back side of the transistor 200 and a front side of the transistor 200.

FIG. 2B shows a view of the interior of the transistor 200 along the Y cross-section line shown in FIG. 2A. As shown in FIG. 2B, a channel structure 214 is disposed within the filling metal 206. The channel structure 214 includes one or more channels 216 (e.g., nanostructure channels) that extend through the filling metal 206 between the source/drains 204. The one or more channels 216 may carry a charge, based on an interaction with the filling metal 206, from the filling metal 206 to the source/drains 204 during operations of the transistor 200. The one or more channels 216 may include a silicon-based material, among other semiconductor materials.

The transistor 200 may include an interfacial layer 218 and/or a high-k dielectric layer 220 disposed around the one or more channels 216. For example, the interfacial layer 218 may be disposed directly on the one or more channels 216 and the high-k dielectric layer 220 may be disposed directly on the interfacial layer 218. In some implementations, the interfacial layer 218 may include a tunneling dielectric (e.g., an oxide layer, a silicon oxide layer, and/or a silicon dioxide layer, among other examples) that may be disposed directly on the channel structure 214 (e.g., directly on the one or more channels 216). In some implementations, the high-k dielectric layer 220 may include a hafnium oxide-based material (e.g., hafnium oxide or hafnium dioxide), among other high-k materials.

As shown in FIG. 2B, material of the interfacial layer 218 and/or the high-k dielectric layer 220 may be disposed on a top surface of the substrate 202. This may be based on a technique (e.g., chemical vapor deposition) used to deposit the interfacial layer 218 and/or the high-k dielectric layer 220.

The transistor 200 further includes a WFM 222, that includes aluminum and carbon, disposed around the channel structure 214. In some implementations, the WFM 222 may have a concentration of titanium in a range from 0% to less than 1.5% (e.g., the WFM may be titanium-free). Based on the WFM 222 having a concentration of titanium that is less than 1.5%, the WFM 222 may have a thickness that it less than 12 angstroms and/or may avoid an uneven thickness of the WFM 222.

The WFM 222 may be disposed around individual channels 216 of the channel structure 214. The WFM 222 may be disposed between individual channels 216 of the channel structure 214. In some implementations, the WFM 222 may be disposed between the individual channels 216 to the exclusion of the filling metal 206 between the individual channels 216. In some implementations, the WFM 222 is disposed between the channel structure 214 and the filling metal 206. In some implementations, the high-k dielectric layer 220 is disposed between the interfacial layer 218 and the WFM 222. In some implementations, the WFM 222 is in direct contact with the high-k dielectric layer 220 or the interfacial layer 218.

The WFM 222 may include an n-type WFM or a p-type WFM. For example, the WFM 222 may be used as a WFM when the source/drains 204 are associated with a p-metal-oxide-semiconductor (MOS) region of the electronic device or an n-MOS region of the electronic device.

FIG. 2C shows a view of the interior of the transistor 200 along the X cross-section line shown in FIG. 2A. As shown in FIG. 2C, the one or more channels 216 of the channel structure 214 extend between the source/drains 204 through a gate region of the transistor 200 that includes the WFM 222 and the filling metal 206 (collectively, “the gate”).

As shown in FIG. 2C, the gate region includes the one or more channels 216 surrounded (e.g., encapsulated) by the interfacial layer 218 between inner spacers 224 (e.g., a low-k dielectric material) and then encapsulated by the inner spacers 224 between the interfacial layer 218 and the source/drains 204. In this way, the one or more channels 216 are electrically insulated from the gate. Additionally, the inner spacers 224 may provide additional electrical isolation between the gate and the source/drains 204. The inner spacers 224 may have a thickness in a range from approximately 15 A to approximately 300 A.

As also shown in FIG. 2C, the WFM 222 may be encapsulated and/or lined with the high-k dielectric layer 220. In this way, the WFM 222 may avoid contacting the interfacial layer 218, which may otherwise cause deterioration of the interfacial layer 218 and/or failure of the transistor 200.

FIG. 2C shows a Z1 cross-section line that extends between a left side of the transistor 200 and a right side of the transistor 200 across a WFM 222. FIG. 2C also shows a Z2 cross-section line that extends between a left side of the transistor 200 and a right side of the transistor 200 across an individual channel 216.

FIG. 2D shows a view of the interior of the transistor 200 along the Z1 cross-section line shown in FIG. 2C. FIG. 2D is a top-down view of the transistor 200 as shown in FIG. 2A, with the view shown at a height of the transistor 200 that is between the one or more channels 216.

As shown in FIG. 2D, the WFM 222 is lined on lateral sides by the high-k dielectric layer 208. The WFM 222 is insulated from the source/drains 204 by the gate spacers 210 (e.g., displaced from the one or more channels 216 in the top-down view) and by the inner spacers 224 (e.g., disposed directly below the one or more channels 216 in the top-down view).

FIG. 2E shows a view of the interior of the transistor 200 along the Z2 cross-section line shown in FIG. 2C. FIG. 2E is a top-down view of the transistor 200 as shown in FIG. 2A, with the view shown at a height of the transistor 200 that includes a channel 216.

As shown in FIG. 2E, the channel 216 is lined with the interfacial layer 218 in a middle portion of the channel 216 and is lined with the gate spacers 210 at end portions (e.g., adjacent to the source/drains 204). The end portions of the channel 216 may be disposed directly on and/or directly below the inner spacers 224 shown in FIG. 2D.

As also shown in FIG. 2E, the WFM 222 is disposed around a front surface (shown as a bottom surface in FIG. 2E) and around a back surface (shown as a top surface in FIG. 2E) of the channel 216 at a middle portion of the channel 216. The WFM 222 is separated from the channel by the interfacial layer 218 and the high-k dielectric layer 208.

Based on using the WFM 222 as the WFM of the transistor 200 (e.g., a nanosheet transistor), the transistor 200 may have a Vt that is tuned with improved precision (e.g., relative to a transistor having a titanium-based WFM) and/or with a Vt that is higher than previous transistors (e.g., a higher Vt component that is attributed to the WFM). In this way, the transistor 200 may be optimized for a Vt that is configured for an application for the transistor 200, which may improve current leakage and/or power consumption of the transistor 200.

As described above, FIGS. 2A-2E are diagrams of an example transistor 200 described herein. Other examples may differ from what is described with regard to FIGS. 2A-2E. The number and arrangement of devices, layers, and/or materials shown in FIGS. 2A-2E are provided as an example. In practice, there may be additional devices, layers, and/or materials, fewer devices, layers, and/or materials, different devices, layers, and/or materials, or differently arranged devices, layers, and/or materials than those shown in FIGS. 2A-2E. Additionally, features described in connection with any of FIGS. 2A-2E may be combined with features described in connection with FIGS. 3A-3F.

FIGS. 3A-3F are diagrams of an example implementation 300 of forming the transistor 200 described herein. The implementation 300 may include one or more operations (e.g., lithography operations, operations performed on different portions of an electronic device that includes the transistor 200) and/or operations shown in the example process may be performed in a different order from the order shown in FIGS. 3A-3F. The transistor 200 may include one or more additional devices, structures, and/or layers not shown in FIGS. 3A-3F. For example, the transistor 200 may include additional layers and/or dies formed on layers above and/or below the portion of the transistor 200 shown in FIGS. 3A-3F. Additionally, or alternatively, one or more additional semiconductor structures and/or semiconductor devices may be formed in a same layer of the electronic device, with a lateral displacement, as the transistor 200 shown in FIGS. 3A-3F.

As shown in FIG. 3A, implementation 300 may include forming a channel structure 214 within a sacrificial material 302. In some implementations, one or more semiconductor processing tools (e.g., deposition tool 102) may deposit the channel structure 214 in alternating layers with the sacrificial material 302 and then may etch into the alternating layers to form one or more channels 216 of the channel structure 214. In some implementations, the sacrificial material 302 may be disposed only vertically between the one or more channels 216 and not laterally between the one or more channels 216.

As shown in FIG. 3B, implementation 300 may include etching away the sacrificial material 302. For example, one or more semiconductor processing tools (e.g., etching tool 104) may apply an etchant, such as a chemical etchant to the sacrificial material 302 to remove the sacrificial material 302. In some implementations, the etchant may be configured to selectively etch material of the sacrificial material 302. In some implementations, the etchant may remove portions of the one or more channels 216 at a slower rate than removal of the sacrificial material 302.

As shown further shown in FIG. 3B, the one or more channels 216 may be suspended above the substrate 202. The one or more channels 216 may be supported by inner spacers (e.g., inner spacers 224 shown in FIG. 2D) after removal of the sacrificial material 302. Additionally, or alternatively, the one or more channels 216 may be supported by coupling to the source/drains 204 after removal of the sacrificial material 302.

As shown in FIG. 3C, implementation 300 may include depositing an interfacial layer 218 on the one or more channels 216 of the channel structure 214. In some implementations, one or more semiconductor processing tools (e.g., deposition tool 102) may deposit material of the interfacial layer 218 on the one or more channels 216 using chemical vapor deposition or atomic layer deposition, among other examples. In some implementations, the interfacial layer 218 may surround the one or more channels 216 to form a liner for the one or more channels 216 within a gate region of the transistor 200.

As shown in FIG. 3D, implementation 300 may include depositing a high-k dielectric layer 220 on the one or more channels 216 of the channel structure 214. In some implementations, one or more semiconductor processing tools (e.g., deposition tool 102) may deposit material of the high-k dielectric layer 220 directly onto the interfacial layer 218 using chemical vapor deposition or atomic layer deposition, among other examples. In some implementations, the high-k dielectric layer 220 may surround the interfacial layer 218 and/or may provide a liner on the interfacial layer 218 and/or gate spacers (e.g., gate spacers 210) of the transistor 200 within the gate region.

As shown in FIG. 3E, implementation 300 may include depositing a WFM 222, that includes aluminum and carbon, within the gate region and around the channel structure 214 (e.g., around the high-k dielectric layer 220). In some implementations, one or more semiconductor processing tools (e.g., deposition tool 102) may deposit material of the WFM 222 using a chemical soaking operation 310. The chemical soaking operation 310 may include applying ILA to the transistor 200 for an amount of time configured to produce the WFM 222 having a desired thickness. In some implementations, the one or more semiconductor processing tools may perform the chemical soaking operation 310 at a temperature in a range of approximately 250 degrees Celsius to 600 degrees Celsius. In this way, the temperature is high enough to support bonding of AlC molecules in the TEA to the high-k dielectric layer 220 and is cool enough to avoid damaging the transistor 200 and/or other semiconductor devices on the electronic device. Additionally, or alternatively, the one or more semiconductor processing tools may perform the chemical soaking operation 310 at a chamber pressure in a range of approximately 0.5 torr to approximately 50 torr. In this way, the pressure used may be within a normal operating range of the deposition tool 102.

In some implementations, the chemical soaking operation 310 may deposit the WFM 222 having a concentration of titanium in a range from 0% to less than 1.5% (e.g., may deposit without a titanium source). In this way, a thickness of the WFM 222 may be in a range from greater than 0 angstroms to less than 12 angstroms (e.g., less than 12 angstroms) and/or may be configured with a thickness that is between multiples of 12 angstroms (e.g., thicknesses based on having higher concentrations of titanium).

In some implementations, the one or more semiconductor processing tools may perform the chemical soaking operation 310 without an atomic layer deposition of WFM. In some implementations, the one or more semiconductor processing tools may perform the chemical soaking operation 310 before an atomic layer deposition of an additional WFM.

As shown in FIG. 3F, implementation 300 may include depositing filling metal 206 around the WFM 222 within a gate region of the transistor 200. In some implementations, one or more semiconductor processing tools (e.g., deposition tool 102) may deposit material of the filling metal 206 around the WFM 222 using reflow, chemical vapor deposition, or plasma vapor deposition, among other examples. In some implementations, a semiconductor processing tool (e.g., planarization tool 106) may polish and/or planarize a top surface of the filling metal 206 to form a generally planar top surface of the transistor 200. In this way, the top surface of the transistor 200 may be suitable for depositing additional material and/or may improve uniformity of a subsequent etching process.

As indicated above, FIGS. 3A-3F are provided as an example. Other examples may differ from what is described with regard to FIGS. 3A-3F. The number and arrangement of devices, layers, and/or materials shown in FIGS. 3A-3F are provided as an example. In practice, there may be additional devices, layers, and/or materials, fewer devices, layers, and/or materials, different devices, layers, and/or materials, or differently arranged devices, layers, and/or materials than those shown in FIGS. 3A-3F.

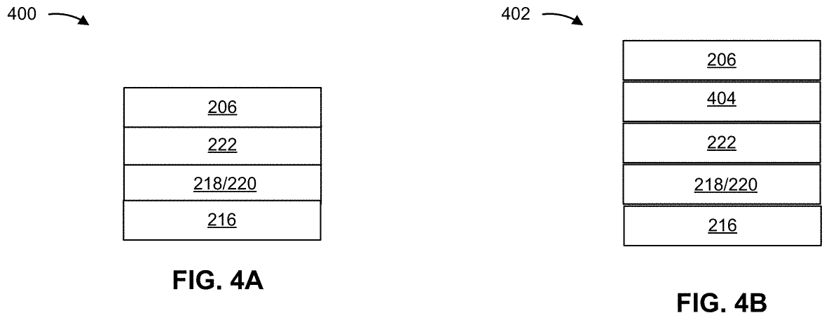

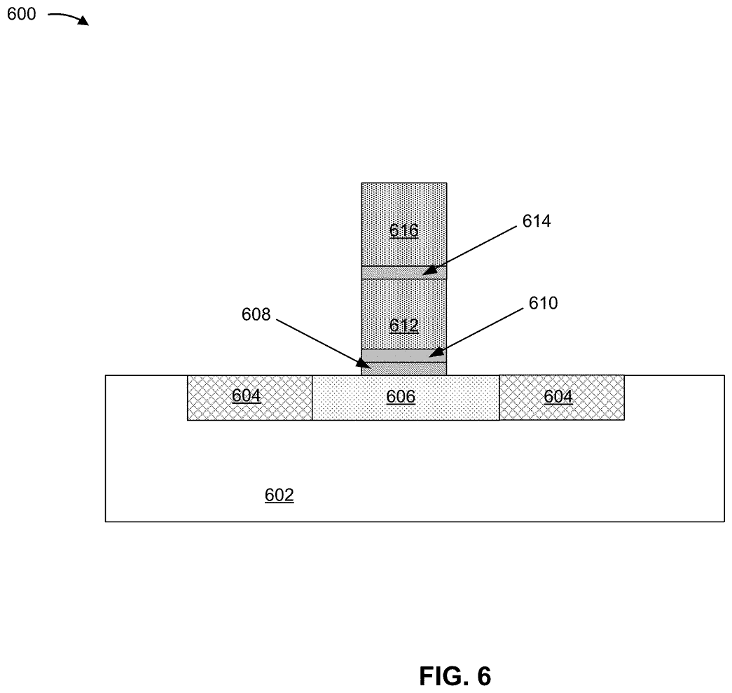

FIGS. 4A-4B are diagrams of examples 400 and 402 of WFM layers described herein. Examples 400 and 402 may include one or more additional layers and/or structures not shown in connection with FIGS. 4A-4B. The examples 400 and 402 may be included in a transistor, such as the transistor 200 shown in FIGS. 2A-2E and/or a transistor manufactured in connection with a process shown in FIGS. 3A-3F. The transistor 200 may include additional layers formed above and/or below the work function material layers shown in FIGS. 4A-4B. The work function material layers shown in FIGS. 4A-4B may include, or may be included in, a nanosheet transistor and/or a FinFET transistor (e.g., shown in connection with FIG. 6).

As shown in FIG. 4A, example 400 includes a channel 216 having an interfacial layer 218 and/or a high-k dielectric layer 220 disposed thereon. The example 400 also includes the WFM 222, that includes aluminum and carbon, disposed on the interfacial layer 218 and/or the high-k dielectric layer 220 as described herein. The example 400 further includes the filling metal 206 disposed on the WFM 222. In some implementations, the WFM 222 may be an only WFM disposed between the channel 216 and the filling metal 206. In this way, the WFM may have a thickness that is in a range of greater than 0 angstroms and less than 12 angstroms. This may support a Vt that is higher than a Vt associated with a thickness that is greater than 12 angstroms, which may improve tuning of the transistor 200 for applications suited for a relatively high Vt. This may improve power consumption and/or current leakage of the transistor 200.

As shown in FIG. 4B, example 402 includes a channel 216 having an interfacial layer 218 and/or a high-k dielectric layer 220 disposed thereon. The example 402 also includes the WFM 222 disposed on the interfacial layer 218 and/or the high-k dielectric layer 220 as described herein. The example 402 additionally includes an additional WFM 404 disposed on (e.g., around) the WFM 222. The additional WFM 404 may include a titanium aluminum carbide (TiAlC) based material or a titanium nitride (TiN) based material. The example 400 further includes the filling metal 206 disposed on the additional WFM 404.

Based on including the WFM 222 and the additional WFM 404, the transistor 200 may be configured with a thickness that is tuned for a Vt associated with a thickness that is greater than 12 angstroms. For example, the transistor 200 may include a number of layers of the additional WFM 404 to provide a coarse thickness of WFM to tune to the Vt and may include a thickness of the WFM 222 to provide a fine tuning of the Vt. This may support tuning a transistor for a Vt that is lower than the Vt of the example 400. This may improve power consumption and/or current leakage of the transistor 200.

As described above, FIGS. 4A-4B are diagrams of example WFM layers described herein. Other examples may differ from what is described with regard to FIGS. 4A-4B. The number and arrangement of devices, layers, and/or materials shown in FIGS. 4A-4B are provided as an example. In practice, there may be additional devices, layers, and/or materials, fewer devices, layers, and/or materials, different devices, layers, and/or materials, or differently arranged devices, layers, and/or materials than those shown in FIGS. 4A-4B. Additionally, features described in connection with any of FIGS. 4A-4B may be combined with features described in connection with FIGS. 2A-3F.

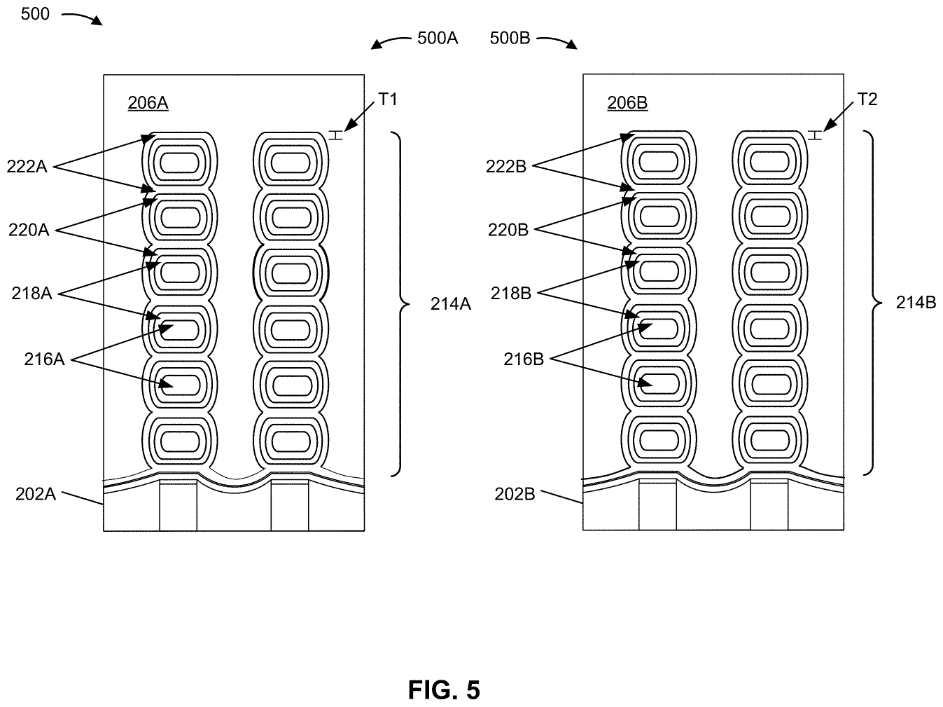

FIG. 5 is a diagram of an example electronic device 500 that includes multiple transistors 500A and 500B described herein. The electronic device 500 may include one or more additional layers and/or structures not shown in connection with FIG. 5. The electronic device 500 may include one or more additional semiconductor structures, such as one or more additional transistors. For example, the electronic device 500 may include additional layers and/or dies formed on layers above and/or below the transistors 500A and 500B shown in FIG. 5. The electronic device 500 may be manufactured using an example process as shown in FIGS. 3A-3F. The electronic device 500 may include multiple nanosheet transistors and/or FinFETs.

As shown in FIG. 5, the electronic device 500 includes a first transistor 500A that includes a first portion 202A of a substrate and a first channel structure 214A that includes a first set 216A of channels. A first interfacial layer 218A is disposed around the first set 216A of channels and a first high-k dielectric layer 220A is disposed around the first interfacial layer 218A. The first transistor 500A further includes a WFM 222A, that includes aluminum and carbon, having a thickness T1 disposed around the first set 216A of channels (e.g., around the first interfacial layer 218A and/or around the first high-k dielectric layer 220A). The first transistor 500A also includes a first filling metal 206A disposed around the WFM 222A.

As further shown in FIG. 5, the electronic device 500 includes a second transistor 500B that includes a second portion 202B of the substrate and a second channel structure 214B that includes a second set 216B of channels. A second interfacial layer 218B is disposed around the second set 216B of channels and a second high-k dielectric layer 220B is disposed around the second interfacial layer 218B. The second transistor 500B further includes an WFM 222B having a thickness T2 (different from T1) disposed around the second set 216B of channels (e.g., around the second interfacial layer 218B and/or around the second high-k dielectric layer 220B). The second transistor 500B also includes a second filling metal 206B disposed around the WFM 222B.

As described in connection with FIG. 5, the electronic device 500 may include different transistors that are tuned with different Vts based on having different thicknesses of WFM (e.g., at least one WFM). In this way, the electronic device 500 may be configured with a first set of transistors that are optimized for a first application associated with a first Vt and with a second set of transistors that are optimized for a second application associated with a second Vt. This may support allocating different transistor-based applications to different transistors of a single electronic device having different Vt tunings, which may improve power consumption and/or current leakage of the electronic device.

As described above, FIG. 5 is a diagram of an example electronic device that includes multiple transistors described herein. Other examples may differ from what is described with regard to FIG. 5. The number and arrangement of devices, layers, and/or materials shown in FIG. 5 are provided as an example. In practice, there may be additional devices, layers, and/or materials, fewer devices, layers, and/or materials, different devices, layers, and/or materials, or differently arranged devices, layers, and/or materials than those shown in FIG. 5. Additionally, features described in connection with FIG. 5 may be combined with features described in connection with FIGS. 2A-4B.

FIG. 6 is a diagram of an example transistor 600 described herein. The electronic transistor 600 may include one or more additional layers and/or structures not shown in connection with FIG. 6. The transistor 600 may include one or more additional semiconductor structures, such as one or more additional transistors. The transistor 600 may include a FinFET.

As shown in FIG. 6, the transistor 600 includes a substrate 602. The substrate 602 may include a semiconductor die substrate, a semiconductor wafer, or another type of substrate in and/or on which semiconductor devices may be formed. In some implementations, the substrate 602 is formed of silicon, a material including silicon, a III-V compound semiconductor material such as gallium arsenide, a silicon on insulator, or another type of semiconductor material. The substrate 602 may form a fin of a FinFET structure.

The transistor 600 also includes source/drains 604 formed at a top surface of the substrate 602. In some implementations, the source/drains 604 may be formed based on doping the substrate 602. The transistor 600 includes a channel 606 disposed within the substrate 602 between the source/drains 604. The channel 606 may be configured to carry a charge between the source/drains 604 during an operation of the transistor 600. The transistor 600 includes a tunneling dielectric 608 disposed on the channel 606. In some implementations, the tunneling dielectric 608 may include an oxide-based material, such as a silicon oxide layer, and/or a silicon dioxide layer, among other examples.

The transistor 600 includes a WFM 610, that includes aluminum and carbon, disposed on the tunneling dielectric 608 and above the channel 606. In some implementations, the WFM 610 may have similar characteristics and/or benefits as the WFM 222 described in connection with FIGS. 2A-5. For example, the WFM 610 includes a concentration of titanium that is in a range of 0% to less than 1.5% of the WFM 610. The WFM 610 may have a thickness that is in a range of greater than 0 angstroms and less than 12 angstroms. Alternatively, the WFM 610 may have a thickness that is in a range of greater than 12n angstroms and less than 12(n+1) angstroms, where n is a number of layers of a titanium-based WFM.

The WFM 610 may include, or may be included in, a floating gate 612 of the transistor 600. The floating gate 612 may further include a filling metal, such as tungsten or cobalt, among other examples. The transistor 600 may include a dielectric layer 614 configured to provide electrical insulation between the floating gate 612 and a control gate 616. The dielectric layer 614 may include silicon dioxide and/or silicon nitride. For example, the dielectric layer 614 may include an oxide-nitride-oxide structure to provide electrical insulation between the floating gate 612 and the control gate 616.

Based on the floating gate 612 including the WFM 610, the transistor 600 may be tuned to a Vt with improved accuracy. For example, a thickness of the WFM 610 may be modified to increase or decrease the Vt without changing a height of a top surface of the floating gate 612. In this way, the transistor 600 may have improved power consumption based on being tuned with improved accuracy.

As described above, FIG. 6 is a diagram of an example transistor described herein. Other examples may differ from what is described with regard to FIG. 6. The number and arrangement of devices, layers, and/or materials shown in FIG. 6 are provided as an example. In practice, there may be additional devices, layers, and/or materials, fewer devices, layers, and/or materials, different devices, layers, and/or materials, or differently arranged devices, layers, and/or materials than those shown in FIG. 6. Additionally, features described in connection with FIG. 6 may be combined with features described in connection with FIGS. 2A-5.

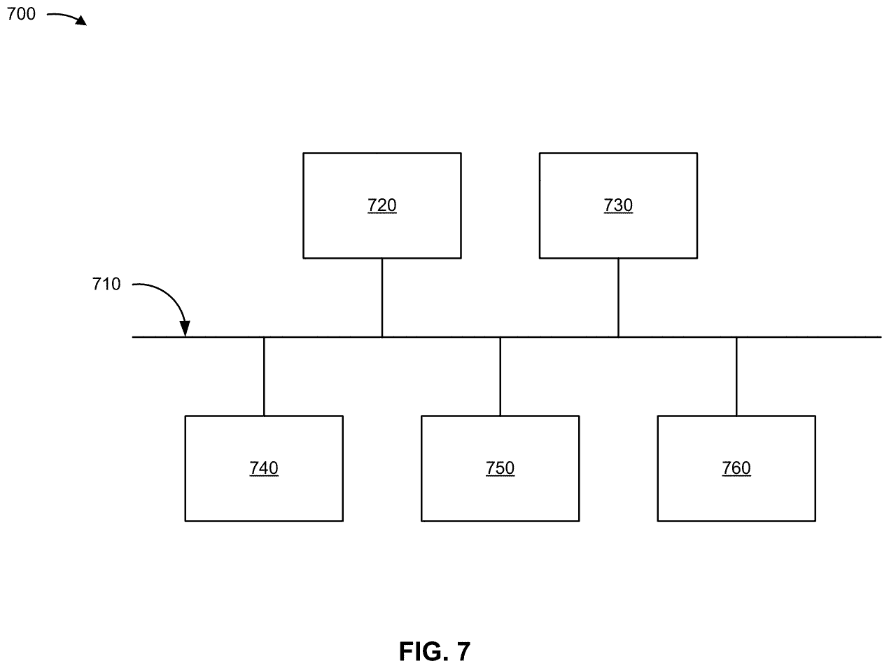

FIG. 7 is a diagram of example components of a device 700, which may correspond to deposition tool 102, etching tool 104, planarization tool 106, and/or wafer/die transport tool 108. In some implementations, deposition tool 102, etching tool 104, planarization tool 106, and/or wafer/die transport tool 108 may include one or more devices 700 and/or one or more components of device 700. As shown in FIG. 7, device 700 may include a bus 710, a processor 720, a memory 730, an input component 740, an output component 750, and a communication component 760.

Bus 710 includes one or more components that enable wired and/or wireless communication among the components of device 700. Bus 710 may couple together two or more components of FIG. 7, such as via operative coupling, communicative coupling, electronic coupling, and/or electric coupling. Processor 720 includes a central processing unit, a graphics processing unit, a microprocessor, a controller, a microcontroller, a digital signal processor, a field-programmable gate array, an application-specific integrated circuit, and/or another type of processing component. Processor 720 is implemented in hardware, firmware, or a combination of hardware and software. In some implementations, processor 720 includes one or more processors capable of being programmed to perform one or more operations or processes described elsewhere herein.

Memory 730 includes volatile and/or nonvolatile memory. For example, memory 730 may include random access memory (RAM), read only memory (ROM), a hard disk drive, and/or another type of memory (e.g., a flash memory, a magnetic memory, and/or an optical memory). Memory 730 may include internal memory (e.g., RAM, ROM, or a hard disk drive) and/or removable memory (e.g., removable via a universal serial bus connection). Memory 730 may be a non-transitory computer-readable medium. Memory 730 stores information, instructions, and/or software (e.g., one or more software applications) related to the operation of device 700. In some implementations, memory 730 includes one or more memories that are coupled to one or more processors (e.g., processor 720), such as via bus 710.

Input component 740 enables device 700 to receive input, such as user input and/or sensed input. For example, input component 740 may include a touch screen, a keyboard, a keypad, a mouse, a button, a microphone, a switch, a sensor, a global positioning system sensor, an accelerometer, a gyroscope, and/or an actuator. Output component 750 enables device 700 to provide output, such as via a display, a speaker, and/or a light-emitting diode. Communication component 760 enables device 700 to communicate with other devices via a wired connection and/or a wireless connection. For example, communication component 760 may include a receiver, a transmitter, a transceiver, a modem, a network interface card, and/or an antenna.

Device 700 may perform one or more operations or processes described herein. For example, a non-transitory computer-readable medium (e.g., memory 730) may store a set of instructions (e.g., one or more instructions or code) for execution by processor 720. Processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry may be used instead of or in combination with the instructions to perform one or more operations or processes described herein. Additionally, or alternatively, processor 720 may be configured to perform one or more operations or processes described herein. Thus, implementations described herein are not limited to any specific combination of hardware circuitry and software.

The number and arrangement of components shown in FIG. 7 are provided as an example. Device 700 may include additional components, fewer components, different components, or differently arranged components than those shown in FIG. 7. Additionally, or alternatively, a set of components (e.g., one or more components) of device 700 may perform one or more functions described as being performed by another set of components of device 700.

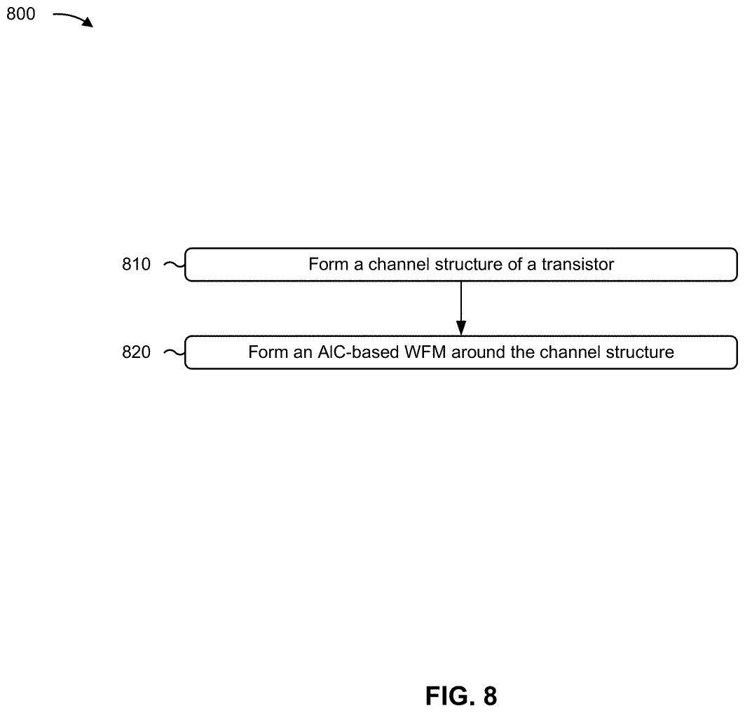

FIG. 8 is a flowchart of an example process 800 associated with a WFM and manufacturing process thereof. In some implementations, one or more process blocks of FIG. 8 may be performed by one or more semiconductor processing tools (e.g., deposition tool 102, etching tool 104, planarization tool 106, and/or wafer/die transport tool 108). Additionally, or alternatively, one or more process blocks of FIG. 8 may be performed by one or more components of device 700, such as processor 720, memory 730, input component 740, output component 750, and/or communication component 760.

As shown in FIG. 8, process 800 may include forming a channel structure of a transistor (block 810). For example, the one or more semiconductor processing tools may form a channel structure 214 of a transistor 200, as described above. In some implementations, the channel structure 214 comprises a plurality of nanostructure channels 216 over a substrate 202 and extending between source/drains of the transistor.

As further shown in FIG. 8, process 800 may include forming an WFM around the channel structure (block 820). For example, the one or more semiconductor processing tools may form an WFM 222 around the channel structure 214, as described above. The WFM 222 may include aluminum and carbon. In some implementations, forming the WFM 222 around the channel structure 214 includes applying a chemical soak. In some implementations, a material of the chemical soak comprises an aluminum, carbon, and hydrogen based material. In some implementations, the WFM 222 comprises a concentration of titanium that is in a range of 0% to less than 1.5% of the WFM 222.

Process 800 may include additional implementations, such as any single implementation or any combination of implementations described below and/or in connection with one or more other processes described elsewhere herein.

In a first implementation, applying the chemical soak comprises applying the material of the chemical soak at a temperature in a range of approximately 250 degrees Celsius to approximately 600 degrees Celsius.

In a second implementation, alone or in combination with the first implementation, process 800 includes depositing an interfacial layer 218 on the channel structure 214, and depositing a high-k dielectric layer 220 on the interfacial layer 218.

In a third implementation, alone or in combination with one or more of the first and second implementations, forming the WFM 222 around the channel structure 214 comprises depositing the WFM 222 around the high-k dielectric layer 220.

In a fourth implementation, alone or in combination with one or more of the first through third implementations, process 800 includes depositing, after forming the WFM 222 around the channel structure 214, a filling metal around the WFM 222.

In a fifth implementation, alone or in combination with one or more of the first through fourth implementations, the WFM 222 has a thickness that is greater than 0 angstroms and less than 12 angstroms.

In a sixth implementation, alone or in combination with one or more of the first through fifth implementations, the channel structure 214 comprises multiple channels 216 extending between source/drains 204 of the transistor 200, and wherein forming the WFM 222 around the channel structure 214 comprises depositing the WFM 222 around individual channels 216 of the multiple channels 216.

Although FIG. 8 shows example blocks of process 800, in some implementations, process 800 may include additional blocks, fewer blocks, different blocks, or differently arranged blocks than those depicted in FIG. 8. Additionally, or alternatively, two or more of the blocks of process 800 may be performed in parallel.

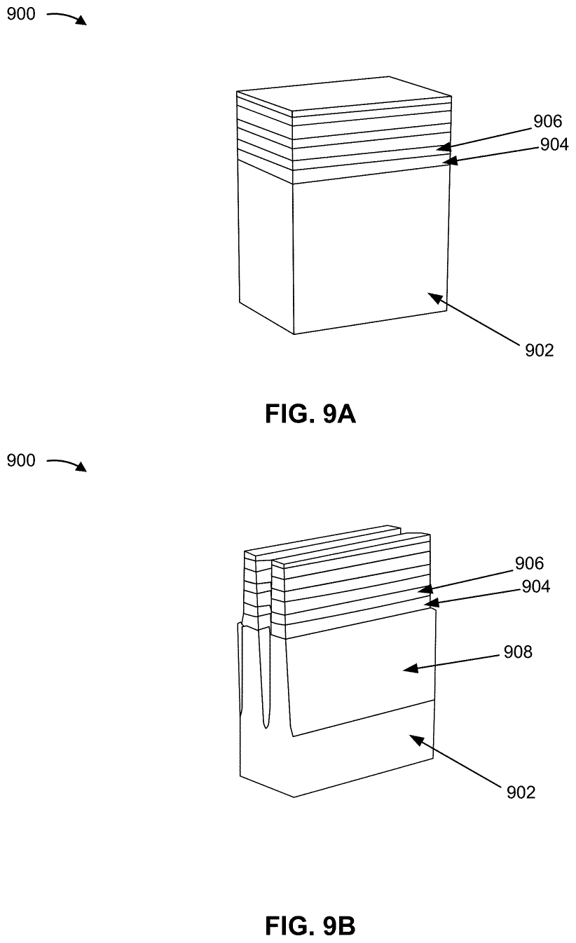

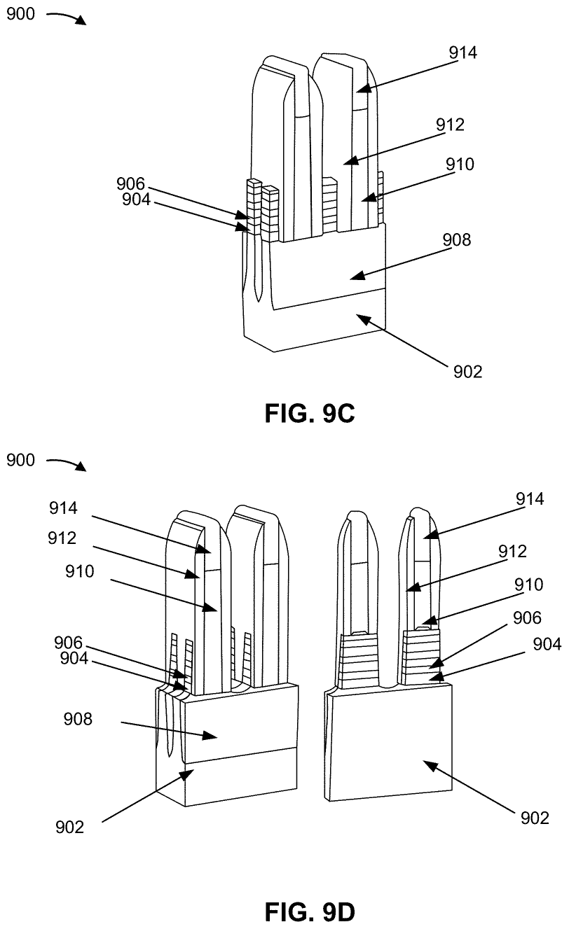

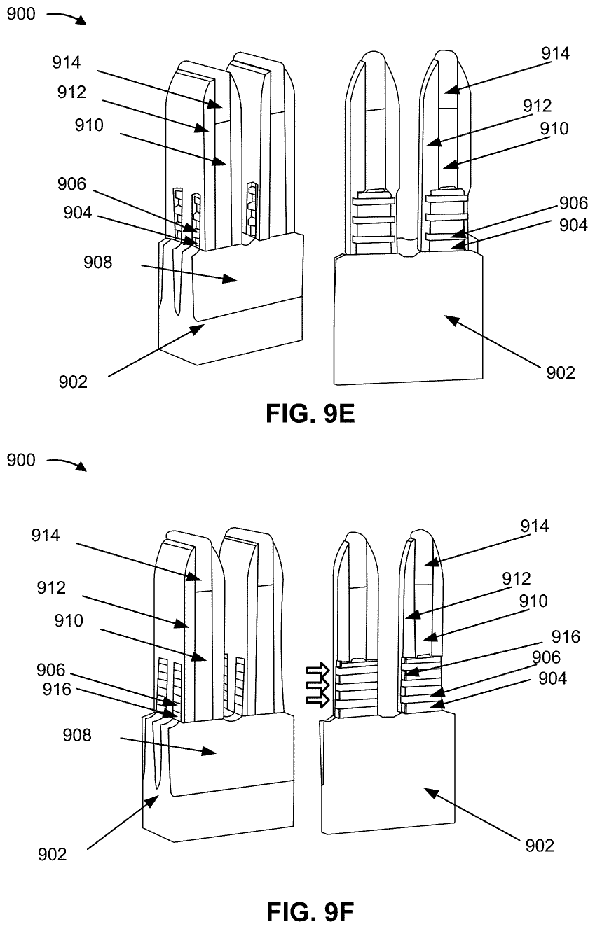

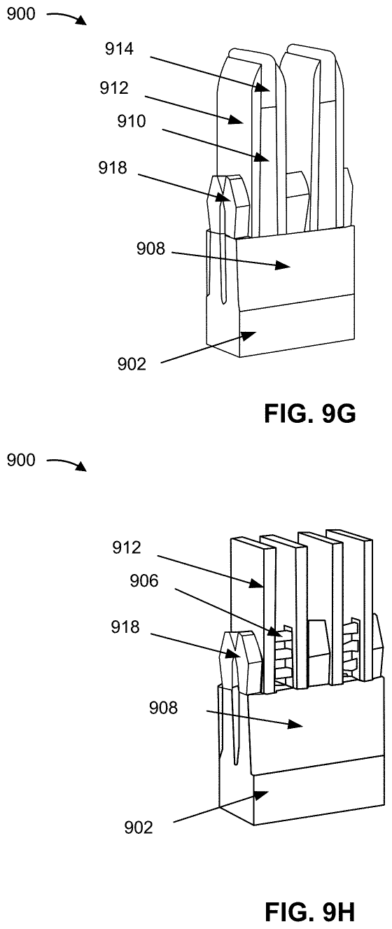

FIGS. 9A-9H are diagrams of an example semiconductor device 900 described herein. Semiconductor device 900 may be manufactured using an example process as shown in FIGS. 9A-9H. The example process may include one or more operations (e.g., lithography operations, operations performed on different portions of an electronic device that includes the semiconductor device 900) and/or operations shown in the example process may be performed in a different order from the order shown in FIGS. 9A-9H. The semiconductor device 900 may include one or more additional devices, structures, and/or layers not shown in FIGS. 9A-9H. For example, the semiconductor device 900 may include additional layers and/or dies formed on layers above and/or below the portion of the semiconductor device 900 shown in FIGS. 9A-9H. Additionally, or alternatively, one or more additional semiconductor structures and/or semiconductor devices may be formed in a same layer of an electronic device that includes the semiconductor device, with a lateral displacement, as the semiconductor device 900 shown in FIGS. 9A-9H. The semiconductor device 900 may be used in a FinFET structure having a narrow critical dimension (e.g., a lateral dimension as shown in FIGS. 9A-9H), such as an N3 FinFET structure and/or a GAA FET structure. In some aspects, the semiconductor device 900 may include the transistor 200 as shown in FIGS. 2A-2E, FIGS. 3A-3F, and/or FIGS. 4A-4B, the electronic device 500, and/or the transistor 600 as shown in FIG. 6.

As shown in FIG. 9A, the semiconductor device 900 includes a stack of nanostructures (e.g., a superlattice growth) deposited on a substrate 902. In some implementations, one or more semiconductor processing tools (e.g., deposition tool 102) deposits a fin stack having alternating layers of silicon-based materials (e.g., nanosheets). The alternating layers of silicon-based materials may include a set of silicon germanium layers 904 and a set of silicon layers 906.

As shown in FIG. 9B, the semiconductor device 900 includes a set of fin stacks that include the alternating layers of silicon-based materials. In some implementations, one or more semiconductor processing tools (e.g., etching tool 104) etch portions of the alternating layers of the stack of nanostructures and the substrate 902 to form the set of fin stacks. One or more semiconductor processing tools (e.g., deposition tool 102) may deposit trench isolation structures 908 (e.g., a shallow trench isolation structure) between fin stacks of the set of fin stacks. The trench isolation structures 908 may include silicon oxide or silicon germanium, among other examples and may be configured to provide electrical insulation and/or isolation between substrate 902 and portions of a set of fins that include the set of fin stacks.

As shown in FIG. 9C, the semiconductor device 900 includes gate structures disposed on top of, between, and/or around the set of fin stacks and on top of the trench isolation structure 908. In some implementations, one or more semiconductor processing tools (e.g., deposition tool 102 and/or etching tool 104) form the gate structure (e.g., having a sacrificial structure 910, a fin sidewall spacer 912, and/or a hard mask layer 914) on top of, between, and/or around the fin stacks. For example, one or more semiconductor processing tools may deposit a layer of the sacrificial structure 910 (e.g., sacrificial material 302) with a generally planar top surface. One or more semiconductor processing tools may etch the sacrificial structure 910 to form inside structures of the gate structures. One or more semiconductor processing tools may deposit a layer of the fin sidewall spacer 912 on the inside structures of the gate structures (e.g., the sacrificial structure 910). One or more semiconductor processing tools may etch a portion of the fin sidewall spacer 912 deposited on a top surface of the sacrificial structure 910 and one or more semiconductor processing tools may deposit the hard mask layer 914 on the top surface of the sacrificial structure 910.

As shown in FIG. 9D, the semiconductor device 900 includes a recessed portion of the fin stacks, which recessed portion separates the fin stacks into separate fin stacks. In some implementations, one or more semiconductor processing tools (e.g., etching tool 104) may etch the fin stacks to form a recessed portion to be used for forming a source/drain region. FIG. 9D includes a first cross-section (e.g., shown on the left of FIG. 9D) that shows a portion of the semiconductor device 900 between fin stacks and a second cross-section (e.g., shown on the right of FIG. 9D) that shows a portion of the semiconductor device 900 on a fin stack.

As shown in FIG. 9E, the semiconductor device 900 includes recessed portions of the set of silicon germanium layers 904. For example, the one or more semiconductor processing tools (e.g., etching tool 104) may etch away portions of the set of silicon germanium layers 904 that are exposed to the recessed portion and/or may etch away silicon nitride and/or silicon carbon oxynitride (SiCON) fin sidewall materials. For example, the one or more semiconductor processing tools may provide methane, trifluoromethane, oxygen gas, hydrogen bromide, silicon tetrachloride, sulfur dioxide, sulfur hexafluoride, helium gas, and/or hydrogen gas, among other examples, as a gas-based etchant. The gas-based etchant may be applied at a pressure in a range of approximately 5 mTorr to approximately 100 mTorr and/or at a temperature in a range of approximately 25 degrees Celsius and approximately 150 degrees Celsius.

As shown in FIG. 9F, the semiconductor device 900 includes inner spacers 916 deposited on surfaces of the recessed portions of the set of silicon germanium layers 904. In some implementations, one or more semiconductor processing tools (e.g., deposition tool 102) deposit material of the inner spacers 916 within the recessed portions of the set of silicon germanium layers 904 and on other materials that form surfaces of the recessed portions. One or more semiconductor processing tools (e.g., etching tool 104) may remove a portion of the material of the inner spacers 916 such that the inner spacers 916 fill the recessed portions of the set of silicon germanium layers 904 to form a substantially smooth surface of the recessed portion of the semiconductor device 900.

As shown in FIG. 9G, the semiconductor device 900 includes epitaxial material 918 formed as source/drains of the semiconductor device 900 between portions of the fin stacks. In some implementations, one or more semiconductor processing tools (e.g., deposition tool 102) deposit material for the source/drains as described herein (e.g., in connection with FIGS. 2A-2E and/or in connection with FIGS. 3A-3F).

As shown in FIG. 9H, the semiconductor device 900 includes a void between the fin sidewall spacer 912 and the silicon nanostructures 906 (e.g., the one or more channels 216). For example, one or more semiconductor processing tools (e.g., etching tool 104) may etch the hard mask 914 and the sacrificial structure 910 to form the void between the fin sidewall spacer 912 and the silicon nanostructures 906 (e.g., as described in connection with FIG. 3B).

In some implementations, one or more semiconductor processing tools may deposit one or more gate materials within the void to form a gate of the semiconductor device that operates in connection with the silicon nanostructures 906 (e.g., as channels) and the epitaxial material 918 (e.g., as source/drains) of the semiconductor device 900. For example, the one or more semiconductor processing tools may perform one or more operations described in connection with FIGS. 3B-3F.

As indicated above, FIGS. 9A-9H are provided as an example. Other examples may differ from what is described with regard to FIGS. 9A-9H. The number and arrangement of devices, layers, and/or materials shown in FIGS. 9A-9H are provided as an example. In practice, there may be additional devices, layers, and/or materials, fewer devices, layers, and/or materials, different devices, layers, and/or materials, or differently arranged devices, layers, and/or materials than those shown in FIGS. 9A-9H. In some implementations, a planarization tool 106 may be used to planarize one or more materials of the semiconductor device 900 after a deposition or etching operation. In this way, a top surface of the semiconductor device 900 may be suited for further deposition and/or etching operations.

Based on using a WFM that includes aluminum and carbon (e.g., a titanium-free WFM), the WFM may have a thickness that is between 0 angstroms and less than 12 angstroms and/or may be tuned to a thickness in a range of greater than 12n angstroms and less than 12(n+1) angstroms, where n is a number of layers of a titanium-based WFM. Based on having improved tuning of the Vt of the transistor, the transistor may be optimized to improve power efficiency and/or current leakage, among other examples.

As described in greater detail above, some implementations described herein provide a transistor. The transistor includes a nanostructure vertically arranged above a substrate. The transistor includes a channel structure of the nanostructure, the channel structure comprising a plurality of nanostructure channels over the substrate and extending between source/drains of the transistor. The transistor includes a WFM, that includes aluminum and carbon, disposed around the plurality of nanostructure channels of the channel structure and separated from the source/drains by one or more inner spacers, where the WFM comprises a concentration of titanium that is in a range of 0% to less than 1.5% of the WFM.

As described in greater detail above, some implementations described herein provide a method. The method includes forming a channel structure of a transistor, the channel structure comprising a plurality of nanostructure channels over a substrate and extending between source/drains of the transistor. The method includes forming a WFM, that includes aluminum and carbon, around the channel structure, where forming the WFM around the channel structure includes applying a chemical soak, where a material of the chemical soak comprises an aluminum, carbon, and hydrogen based material, and where the WFM comprises a concentration of titanium that is in a range of 0% to less than 1.5% of the WFM.

As described in greater detail above, some implementations described herein provide a transistor. The transistor includes source/drains formed on a surface of a substrate of the transistor. The transistor includes a channel extending between the source/drains and within the substrate. The transistor includes a WFM, that includes aluminum and carbon, disposed above the channel, where the WFM comprises a concentration of titanium that is in a range of 0% to less than 1.5% of the WFM. The transistor includes a gate disposed on the WFM.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A transistor comprising:
a nanostructure vertically arranged above a substrate;
a channel structure of the nanostructure, the channel structure comprising a plurality of nanostructure channels over the substrate and extending between source/drains of the transistor; and
a work function material (WFM), that includes aluminum and carbon, disposed around the plurality of nanostructure channels of the channel structure and separated from the source/drains by one or more inner spacers,
wherein the WFM comprises a concentration of titanium that is in a range of 0% to less than 1.5% of the WFM.

2. The transistor of claim 1, wherein the WFM is disposed between the plurality of nanostructure channels and a filling metal of the transistor.

3. The transistor of claim 1, wherein the transistor comprises a nanosheet transistor.

4. The transistor of claim 1, wherein the channel structure comprises multiple channels, and
wherein the WFM is disposed around individual channels of the multiple channels.

5. The transistor of claim 1, further comprising one or more of:
an interfacial layer disposed between the WFM and the channel structure,
a high-k dielectric layer disposed between the WFM and the channel structure, or
an additional WFM disposed around the WFM.

6. The transistor of claim 5, wherein the interfacial layer comprises an oxide layer disposed directly on the channel structure.

7. The transistor of claim 5, wherein the high-k dielectric layer comprises a hafnium oxide-based material disposed between the interfacial layer and the WFM.

8. The transistor of claim 5, wherein the additional WFM comprises one or more of:
a titanium aluminum carbide (TiAlC) based material, or
a titanium nitride (TiN) based material.

9. The transistor of claim 1, wherein the WFM is an n-type WFM or a p-type WFM.

10. A method, comprising:
forming a channel structure of a transistor, the channel structure comprising a plurality of nanostructure channels over a substrate and extending between source/drains of the transistor; and
forming a work function material (WFM), that includes aluminum and carbon, around the channel structure,
wherein forming the WFM around the channel structure includes applying a chemical soak,
wherein a material of the chemical soak comprises an aluminum, carbon, and hydrogen based material, and
wherein the WFM comprises a concentration of titanium that is in a range of 0% to less than 1.5% of the WFM.

11. The method of claim 10, wherein applying the chemical soak comprises:
applying the material of the chemical soak at a temperature in a range of approximately 250 degrees Celsius to approximately 600 degrees Celsius.

12. The method of claim 10, further comprising:
depositing an interfacial layer on the channel structure; and
depositing a high-k dielectric layer on the interfacial layer.

13. The method of claim 12, wherein forming the WFM around the channel structure comprises:
depositing the WFM around the high-k dielectric layer.

14. The method of claim 10, further comprising:
depositing, after forming the WFM around the channel structure, a filling metal around the WFM.

15. The method of claim 10, further comprising:
forming the WFM around an additional channel structure of an additional transistor of a same electronic device as the transistor,
wherein the WFM has a first thickness around the channel structure, and
wherein the WFM has a second thickness around the additional channel structure,
wherein the first thickness is different from the second thickness.

16. The method of claim 10, wherein the WFM has a thickness that is greater than 0 angstroms and less than 12 angstroms.

17. The method of claim 10, wherein the channel structure comprises multiple channels extending between source/drains of the transistor, and
wherein forming the WFM around the channel structure comprises depositing the WFM around individual channels of the multiple channels.

18. A transistor comprising:
source/drains formed on a surface of a substrate of the transistor;
a channel extending between the source/drains and within the substrate; and
a work function material (WFM), that includes aluminum and carbon, disposed above the channel,
wherein the WFM comprises a concentration of titanium that is in a range of 0% to less than 1.5% of the WFM; and
a gate disposed on the WFM.

19. The transistor of claim 18, wherein the transistor comprises a fin field effect transistor (FinFET) transistor.

20. The transistor of claim 18, further comprising a tunneling dielectric between the channel and the WFM.
